(19) United States
(12) Patent Application Publication
(10) Pub. No.: US 2026/0029464 A1
(43) Pub. Date: Jan. 29, 2026

(54) JITTER SENSOR CIRCUIT

(71) Applicant: Apple Inc., Cupertino, CA (US)

(72) Inventors: Saikrishna GANTA, San Jose, CA (US); Man-Chia CHEN, Milpitas, CA (US); Mansour KERAMAT, Los Gatos, CA (US); Mohammad Tabish SIDDIQUI, San Ramon, CA (US); Si CHEN, Fremont, CA (US); Soumya CHAKRABORTY, Cupertino, CA (US)

(21) Appl. No.: 18/785,832

(22) Filed: Jul. 26, 2024

(51) Int. Cl. G01R 31/317

(52) U.S. Cl. CPC G01R 31/31709; G01R 31/31703; G01R 31/31727

(57) ABSTRACT

A jitter sensor circuit for measuring jitter of a clock signal is disclosed. The jitter sensor circuit includes a time-to-voltage converter circuit that is activated at random intervals to generate, using a reference voltage, a signal whose voltage is proportional to a portion of a period of the clock signal. The jitter sensor circuit also includes an analog-to-digital converter circuit that converts the output signal of the time-to-voltage converter circuit to a digital value using the same reference voltage as the time-to-voltage converter circuit.

### FIELD

The described embodiments relate generally to computer systems and, more particularly, to techniques for measuring jitter in clock signals.

### BACKGROUND

Modern computer systems may include multiple circuit blocks designed to perform various functions. For example, such circuit blocks may include processors or processor cores configured to execute software or program instructions. Additionally, the circuit blocks may include memory circuits, mixed-signal circuits, analog circuits, and the like.

Some computer systems include circuit blocks that include digital circuits that operate using a periodic digital signal referred to as a “clock signal.” Various circuits may be used to generate clock signals in a computer system. For example, in some computer systems, a crystal oscillator circuit or an inductor-capacitor oscillator circuit (referred to as an “LC oscillator circuit”) may be used to generate a clock signal that has a particular frequency. Clock signals of other frequencies can be generated using phase-locked loop circuits, delay-locked loop circuits, or frequency-divider circuits.

### BRIEF DESCRIPTION OF THE DRAWINGS

FIG. 1 is a block diagram depicting an embodiment of a jitter sensor circuit.

FIG. 2 is a block diagram depicting an embodiment of a time-to-voltage converter circuit.

FIG. 3 is a block diagram depicting an embodiment of a reference circuit.

FIG. 4 is a block diagram depicting an embodiment of an analog-to-digital converter circuit.

FIG. 5 is a block diagram depicting an embodiment of a digital-to-analog converter circuit for use in an analog-to-digital converter circuit.

FIG. 6 is a block diagram depicting an embodiment of an integrated circuit that includes a jitter sensor circuit.

FIG. 7 is a flow diagram depicting an embodiment of a method for operating a jitter sensor circuit.

FIG. 8 is a block diagram of an embodiment of a device that includes jitter sensor circuits.

FIG. 9 is a block diagram of various embodiments of computer systems that may include jitter sensor circuits.

FIG. 10 illustrates an example of a non-transitory computer-readable storage medium that stores circuit design information.

### DETAILED DESCRIPTION

Computer systems may include multiple circuit blocks configured to use periodic signals, referred to as clock signals, to perform various operations. For example, in some computer systems, one or more clock signals may be used to send data from one device to another within the computer system. In such cases, the one or more clock signals may be transmitted along with the data, and the receiving device may use the one or more clock signals to sample the received data.

A variety of techniques may be employed to generate the various clock signals a computer system may employ. In some cases, a crystal-oscillator circuit or an inductor-capacitor oscillator circuit (referred to as an “LC oscillator circuit”) may be used to generate a base clock signal that can be used in the generation of other clock signals of various frequencies.

Due to variation in clock generation circuits and the operating conditions (e.g., power supply voltage, temperature, and the like) of such clock generation circuits, the generation of clock signals is imperfect resulting in jitter in the clock signals. As used herein, jitter refers to deviation in a clock signal from its ideal periodicity. Jitter can change the period of a clock signal from one cycle to another by causing clock edges (both rising and falling edges) to deviate from their ideal positions.

Jitter can cause timing failures within an integrated circuit, preventing an integrated circuit from operating at a desired frequency. Additionally, as clock frequencies have increased, jitter can consume a larger portion of a unit interval in high-speed data communication making proper operation of a communication system difficult. To better understand how the various operating conditions affect clock jitter so that better clock generator circuits can be designed, clock signals may be routed to terminals (e.g., solder bumps) that allow external test circuits to measure the jitter associated with the clock signals.

To determine the jitter of high-frequency clock signals, accurate measurements are needed. Sending a clock signal off-chip to an external measurement circuit can limit the accuracy with which a jitter measurement can be made. Moreover, in some computer systems, multiple chiplets may be assembled together preventing easy access to test terminals of the chiplets.

The embodiments illustrated in the drawings and described below may provide techniques for on-chip measurement of clock jitter. By measuring jitter on-chip, inaccuracies induced in the measurement by transmitting the clock signal off-chip can be eliminated. Moreover, on-chip jitter measurement can allow for measurements to be performed during normal operation of an integrated circuit without the use of an external test bench setup.

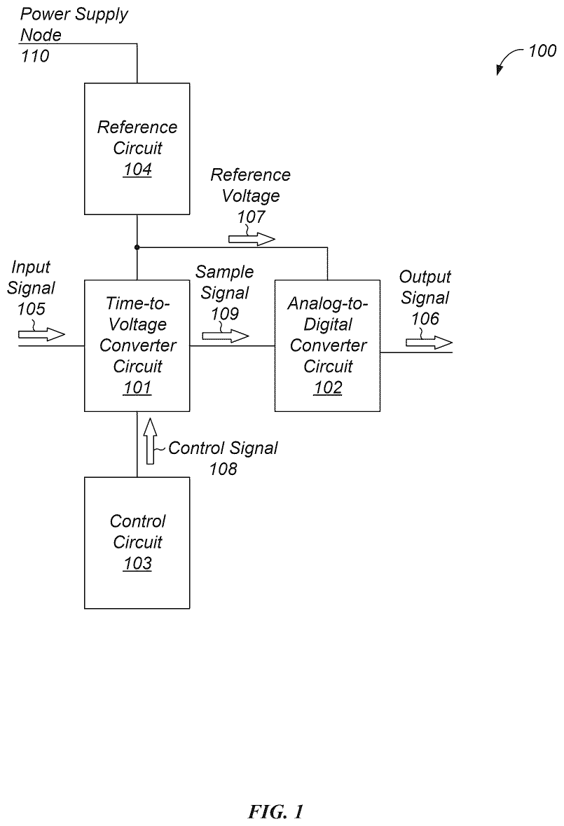

A block diagram of a jitter sensor circuit is depicted in FIG. 1. As illustrated, jitter sensor circuit 100 includes time-to-voltage converter circuit 101, analog-to-digital converter circuit 102, control circuit 103, and reference circuit 104.

Reference circuit 104 is configured to generate reference voltage 107 using a voltage level of power supply node 110. As described below, reference circuit 104 may, in some embodiments, be implemented as a resistive voltage-divider circuit.

Time-to-voltage converter circuit 101 is configured, in response to being activated by control signal 108, to generate sample signal 109 using reference voltage 107. In various embodiments, a voltage level of sample signal 109 is proportional to a portion of a period of input signal 105. For example, in some embodiments, the voltage level of sample signal 109 is proportional to the period of time input signal 105 is a logical-1 value while, in other embodiments, the voltage level of sample signal 109 may be proportion to a fraction of the period of time input signal 105 is a logical-1. It is noted that, in various embodiments, input signal 105 may be a clock or other timing reference signal used as a time base for circuit blocks in a computer system.

Control circuit 103 is configured to generate control signal 108. In some embodiments, control signal 108 has a period equal to that of input signal 105 while is other embodiments, control signal 108 may have any suitable period. As described above, control signal 108 is used to activate time-to-voltage converter circuit 101, whose output, i.e., sample signal 109, is digitized using analog-to-digital converter circuit 102. To supports input signal frequencies greater than few GHZ, down-stream circuits, e.g., analog-to-digital converter circuit 102, may have to operate at high bandwidths, which may be prohibitive in terms of circuit area and power consumption. To remediate such circuit are and power consumptions issues, control circuit 103 may, in some embodiments, be configured to wait a random time period between activations of control signal 108. By employing random time periods between activations of control signal 108, time-to-voltage converter circuit 101 can sub-sample input signal 105 without introducing blind spots in the sampling. That is, assuming cyclo-stationary signals, sample signal 109 would have similar properties when sub-sampled and it would when it was sampled at high speed. By reducing a number of samples per unit time, the performance requirements of down-stream circuits can be reduced. Control circuit 103 may, in various embodiments, be implemented using any suitable combination of sequential and combinatorial logic circuits.

Analog-to-digital converter circuit 102 is configured to generate, using reference voltage 107, output signal 106 based on sample signal 109. As described above, reference voltage 107 is also used by time-to-voltage converter circuit 101. By using the same power supply voltage level for both sampling and digitizing, the accuracy requirements for reference voltage 107 can be reduced as depicted in Equation 1, where V₁₀₆ is the voltage level of output signal 106, V₁₀₇ is the voltage level of reference voltage 107, R is value of resistor 201, C is the value of capacitor 203, T_{P} is the period of input signal 105, tⱼ is the jitter associated with input signal 105, and Vₙₒᵢₛₑ is the quantization noise of analog-to-digital converter circuit 102. Since V₁₀₇ is a common term between the numerator and denominator of Equation 1, V₁₀₆ is independent of the value of reference voltage 107, thereby allowing the accuracy requirements for reference voltage 107 to be reduce.

$${V}_{106} = \frac{{V}_{107} - \frac{{V}_{107}}{R C} {T}_{P} - \frac{{V}_{107}}{R C} {t}_{j}}{{V}_{107}} + {V}_{n o i s e} . \qquad ( 1 )$$

According to Equation 1, the voltage level of output signal 106 is sensitive to the values of resistor 201 and capacitor 203. It is noted, however, that both T_{P} and jitter tⱼ have similar dependence on the values of resistor 201 and capacitor 203. Be measuring the jitter as a ratio with respect to period as shown in Equation 2, the. dependence on the values of resistor 201 and capacitors 203 is removed.

$$\frac{{V}_{106 \_ jitter} = \frac{\frac{{V}_{107}}{RC} {t}_{j}}{{V}_{107}}}{1 - {V}_{106 \_ static} = \frac{\frac{{V}_{107}}{RC} {T}_{p}}{{V}_{107}}} . \qquad ( 2 )$$

In various embodiments, output signal 106 includes a plurality of bits whose value is indicative of the period of time input signal 105 is at the particular logic value. As described below, analog-to-digital converter circuit 102 may be implemented as a successive-approximation analog-to-digital converter circuit, or any other suitable analog-to-digital converter circuit configured to digitize sample signal 109 using reference voltage 107.

It is noted that while the embodiment of FIG. 1 describes using a single-ended input signal, in other embodiments, input signal 105 may be a differential input signal. In such cases, time-to-voltage converter circuit 101 may be configured to sample a difference between the two signals that are included in input signal 105 in order to generate sample signal 109. Alternatively, time-to-voltage converter circuit 101 may be configured to separately sample the two signals included in input signal 105 to generate a differential version of sample signal 109.

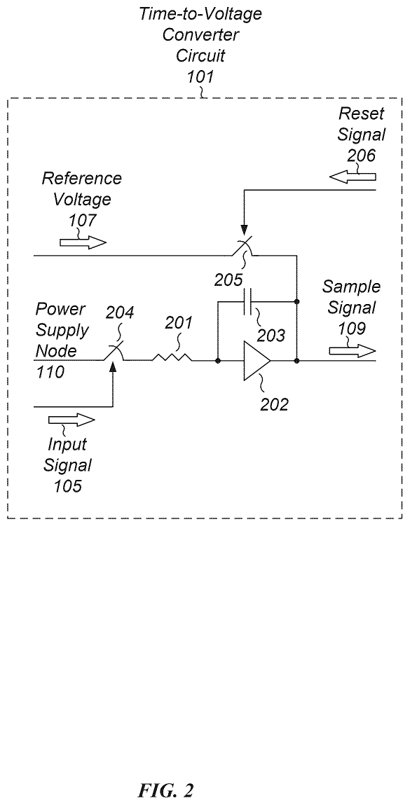

Turning to FIG. 2, a block diagram of an embodiment of time-to-voltage converter circuit 101 is depicted. As illustrated, time-to-voltage converter circuit 101 includes resistor 201, amplifier circuit 202, capacitor 203, and switches 204 and 205.

Switch 204 is coupled between power supply node 110 and resistor 201, and is controlled by input signal 105. When switch 204 is closed, power supply node 110 is coupled to a terminal of resistor 201. Switch 205 is coupled between reference voltage 107 and an output of amplifier circuit 202 and is controlled by reset signal 206.

Resistor 201 is coupled between switch 204 and an input of amplifier circuit 202. Capacitor 203 is coupled between the output of amplifier circuit 202 and the input of amplifier circuit 202. Collectively, resistor 201, amplifier circuit 202, and capacitor 203 operate as an integrator circuit configured to generate, when switch 204 is closed, sample signal 109 such that a voltage level of sample signal 109 is proportional to all or a portion of the period of input signal 105. In some cases, the portion of the period of input signal 105 may correspond to a time that the value of input signal 105 is a logical-1, while in other cases, the portion of the period of input signal may correspond to a time that the value of input signal 105 is a logical-0. In various embodiments, time-to-voltage converter circuit 101 may generate sample signal 109 such that the value of sample signal 109 is also proportional to a reciprocal of the product of the respective values of resistor 201 and capacitor 203.

In various embodiments, before every measurement reset signal 206 is activated, closing switch 205. With the closing of switch 205 the output of amplifier circuit 202 is coupled to reference voltage 107, setting the value of sample signal 109 to that of reference voltage 107 in preparation for integration period. The integration period begins after reset signal 206 is deactivated and input signal 105 is asserted.

Once the integration period, i.e., the time input signal 105 is at the particular logic value, ends, switch 204 is opened. At this point, amplifier circuit 202 sets the voltage of sample signal 109 to an analog voltage which is proportional to the integration time period plus any jitter associated with the integration time period.

In some embodiments, amplifier circuit 202 may be implemented as an operational amplifier circuit, or any other suitable amplifier circuit. In various embodiments, resistor 201 may be implemented using polysilicon, diffusion, metal, or any other suitable material available in a semiconductor manufacturing process. In some embodiments, capacitor 203 may be implemented using a metal-oxide-metal (“MOM”) structure, a metal-insulator-metal (“MIM”) structure, or any other suitable capacitor structure available in a semiconductor manufacturing process.

Switches 204 and 205 may, in various embodiments, be implemented as pass gates or any other suitable switch circuits. In various embodiments, the pass gates may be implemented using at least one metal-oxide semiconductor field-effect transistors (“MOSFET”). In some embodiments, the pass gates may be implemented using at least one n-channel MOSFET and at least one p-channel MOSFET.

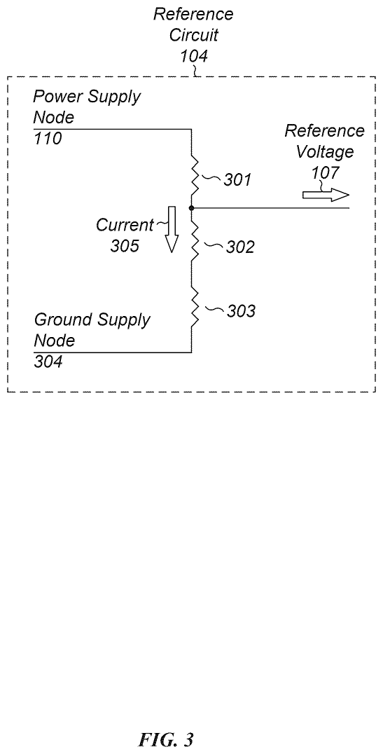

Turning to FIG. 3, a block diagram of an embodiment of reference circuit 104 is depicted. As illustrated, reference circuit 104 includes resistors 301-303. Although only three resistors are depicted in the embodiment of FIG. 3, in other embodiments, any suitable number of resistors may be employed.

Resistors 301-303 are coupled in series between power supply node 110 and ground supply node 304. Current 305 flow from power supply node 110 to ground supply node 304 through resistors 301-303. In various embodiments, a value of current 305 is determined by the total resistance of resistors 301-303 and a voltage level of power supply node 110.

As current 305 passes through each of resistors 301-303, a respective voltage drop is developed across each of resistors 301-303. Reference voltage 107 is the sum of the voltage drops across resistors 302 and 303. Alternatively, reference voltage 107 can be viewed as the difference between the voltage level of power supply node 110 and the voltage drop across resistor 301.

It is noted that although reference circuit 104 as depicted in FIG. 3 is implemented as a resistive voltage-divider circuit, in other embodiments, reference circuit 104 may be implemented using any suitable circuit configured to generate a reference voltage that can be used by time-to-voltage converter circuit 101 and analog-to-digital converter circuit 102.

Resistors 301-303 may, in various embodiments, be implemented using polysilicon, diffusion, metal, or any other suitable material available as part of a semiconductor manufacturing process.

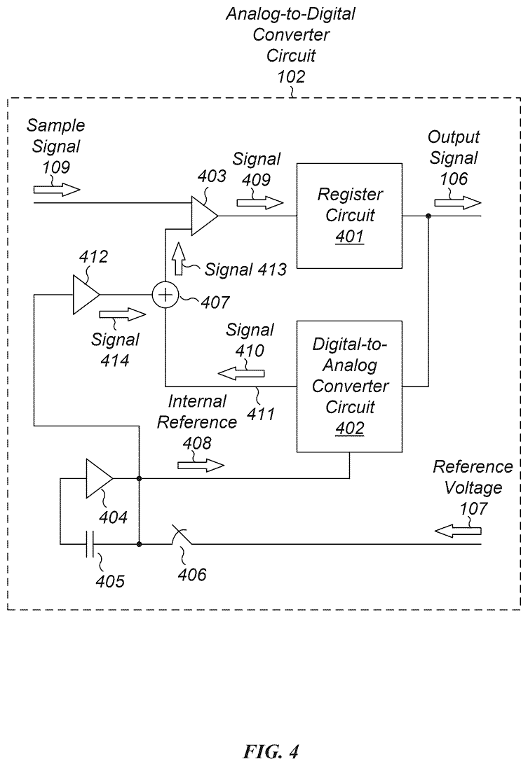

Turning to FIG. 4, a block diagram of an embodiment of analog-to-digital converter circuit 102 is depicted. As illustrated, analog-to-digital converter circuit 102 includes register circuit 401, digital-to-analog converter circuit 402, comparator circuit 403, buffer circuit 404, capacitor 405, switch 406, summer circuit 407, and buffer circuit 412.

Comparator circuit 403 is configured to generate signal 409 using sample signal 109 and signal 413. To generate signal 409, comparator circuit 403 may be configured to perform a comparison operation on sample signal 109 and signal 413, and determine a value for signal 409 based on a result of the comparison. For example, in response to a determination that sample signal 109 is less than signal 413, comparator circuit 403 may be configured to set signal 409 to a particular logical value. In various embodiments, comparator circuit 403 may be implemented using a Schmitt trigger circuit, or any other suitable comparator circuit configured to generate a digital signal based on a comparison of two or more analog input signals.

Register circuit 401 is configured to generate output signal 106 using signal 409. In various embodiments, output signal 106 includes multiple bits, and register circuit 401 is configured to increment or decrement the value of output signal 106 based on a value of signal 409. Register circuit 401 may, in some embodiments, be implemented using multiple latch or flip-flop circuits configured to store respective bits of output signal 106.

Digital-to-analog converter circuit 402 is configured to generate signal 410 using output signal 106 and internal reference 408. As described below, digital-to-analog converter circuit 402 may use multiple capacitors that are coupled to internal reference 408 based on corresponding bits of output signal 106 to generate an analog voltage level for signal 410 that is based on the value of output signal 106.

The output of time-to-voltage converter circuit 101 has a large dynamic range due to the fact that its output, i.e., sample signal 109, includes both a period and jitter component. In order to relax the dynamic range requirement for analog-to-digital converter circuit 102, the period component of sample signal 109 can be canceled. To cancel the period component of sample signal 109, a calibration loop that adjusts the values of resistor201 and capacitor 203 can be employed. The adjustment is performed such that on an average sample signal 109 settles to negative value of reference voltage 107. Post calibration, sample signal 109 is centered, on average, at zero and the only variation in sample signal 109 is due to jitter, thereby reducing the dynamic range of sample signal 109.

Summer circuit 407 is configured to generate signal 413 using signal 414 and signal 410. In various embodiments, signal 414 is the period cancellation signal. In various embodiments, to generate signal 413, summer circuit 407 may be configured to add the respective voltage levels of signal 410 and signal 414. Summer circuit 407 may, in some embodiments, be implemented using an operational amplifier or other suitable circuit. In other embodiments, summer circuit 407 may be omitted in favor of passively combining signal 410 and signal 414 to generate signal 413.

Noise and transients on reference voltage 107 can cause incorrect measurements of jitter and period of input signal 105. Time-to-voltage converter circuit 101 is, however, sensitive to noise on reference voltage 107 only during integration time. To remediate such sensitivity, during integration time, reference voltage 107 is sampled and held on capacitor 405 by using negative feedback from buffer circuit 404. Switch 406 is configured to couple reference voltage 107 to capacitor 405 and the output of buffer circuit 404 during a reset period that occurs just before integration time . . .

Capacitor 405 is coupled between an input of buffer circuit 404 and the output of buffer circuit 404. In various embodiments, capacitor 405 may be implemented using a MOM capacitor structure, a MIM capacitor structure, or any other suitable capacitor structure available on a semiconductor manufacturing process. Although depicted as a single capacitor, in other embodiments, capacitor 405 may be implemented using any suitable parallel and/or series combination of capacitors.

Buffer circuit 404 is configured to generate internal reference 408 using reference voltage 107. During the reset period, reference voltage 107 is directly coupled to the output of buffer circuit 404, thereby generating internal reference 408. During the integration period of time-to-voltage converter circuit 101, switch 406 is open, and buffer circuit 404 maintains the voltage level of internal reference 408. In various embodiments, buffer circuit 404 may be implemented using any suitable unity-gain amplifier circuit.

Buffer circuit 412 is configured to generate signal 414 using internal reference 408. In various embodiments, buffer circuit 412 is configured to generate signal 414 such that signal 414 is a buffered version of internal reference 408. As described above, signal 414 is combined with signal 410 to generate signal 413.

By combining signals 414 and 410, the dynamic range requirements for comparator circuit 403 can be reduced, thereby improving the accuracy of analog-to-digital converter circuit 102. In various embodiments, buffer circuit 412 can be implemented using any suitable unity-gain amplifier circuit.

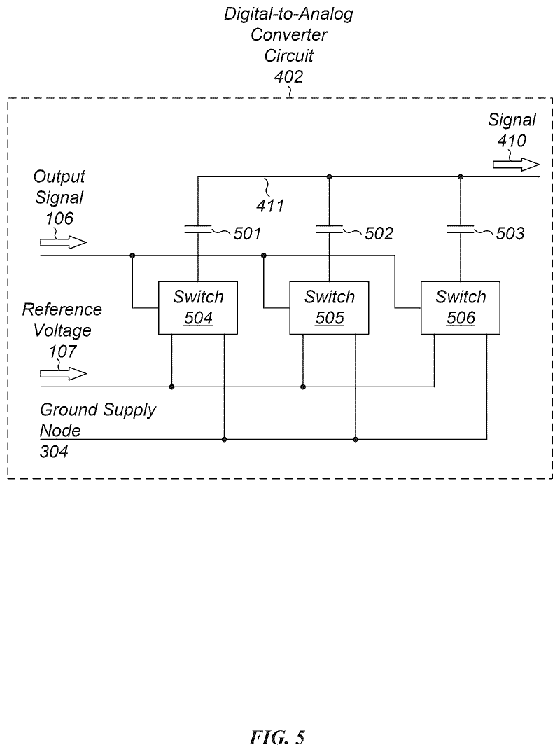

Turning to FIG. 5, a block diagram of digital-to-analog converter circuit 402 is depicted. As illustrated, digital-to-analog converter circuit 402 includes capacitors 501-503 and switches 504-506. Although only three capacitors and their corresponding switches are depicted in the embodiment of FIG. 5, in other embodiments, any suitable number of capacitors and switches may be employed. In some cases, the number of capacitors may correspond to a number of bits included in output signal 106.

Respective first terminals of capacitors 501-503 are coupled to node 411, while respective second terminals are coupled to corresponding ones of switches 504-506. In various embodiments, switches 504-506 are configured to couple the respective second terminals of capacitors 501-503 to either reference voltage 107 or ground supply node 304 based on corresponding bits of output signal 106. As the respective second terminals of capacitors 501-503 are coupled to either reference voltage 107 or ground supply node 304, the changes in voltage are coupled into node 411, generating signal 410.

In some cases, the values of capacitors 501-503 may be binary weighted. For example, the value of capacitor 502 may be half the value of capacitor 501. Capacitors 501-503 may, in various embodiments, be implemented using MOM structures, MIM structures, or any other suitable capacitor structure available in a semiconductor manufacturing process.

Each of switches 504-506 may be implemented using two pass-gate circuits coupled together in a wired-OR fashion, or any other suitable switch circuit. The pass-gate circuits may be implemented using one or more MOSFETs.

It is noted that the embodiment of digital-to-analog converter circuit 402 depicted in FIG. 5 is merely an example. In other embodiments, different digital-to-analog converter circuit topologies, e.g., switched resistor digital-to-analog converter circuits, switched current source digital-to-analog converter circuits, and the like, may be employed.

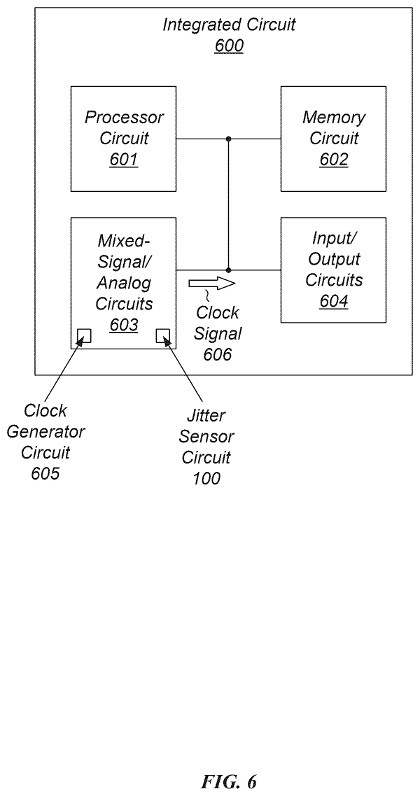

Turning to FIG. 6, a block diagram of an integrated circuit is depicted. As illustrated, integrated circuit 600 includes processor circuit 601, memory circuit 602, mixed-signal/analog circuits 603, and input/output circuits 604. In various embodiments, integrated circuit 600 may be configured for use in a desktop computer, server, or in a mobile computing application such as a tablet, laptop computer, smartphone, or wearable computing device.

Processor circuit 601 may, in various embodiments, be representative of a general-purpose processor that performs computational operations using clock signal 606. For example, processor circuit 601 may be a central processing unit (“CPU”) such as a microprocessor, a microcontroller, an application-specific integrated circuit (“ASIC”), or a field-programmable gate array (“FPGA”).

Memory circuit 602 may, in various embodiments, include any suitable type of memory circuits such as a dynamic random-access memory (“DRAM”) circuit, a static random-access memory (“SRAM”) circuit, a read-only memory (“ROM”) circuit, an electrically erasable programmable read-only memory (“EEPROM”) circuit, or a non-volatile memory circuit, for example. It is noted that although a single memory circuit is illustrated in FIG. 6, in other embodiments, any suitable number of memory circuits may be employed.

Mixed-signal/analog circuits 603 includes clock generator circuit 605 configured to generate clock signal 606. Additionally, mixed-signal/analog circuits 603 includes jitter sensor circuit 100 as depicted in FIG. 1. In various embodiments, clock generator circuit 605 may include a crystal oscillator circuit, a phase-locked loop (“PLL”) circuit, a delay-locked loop (“DLL”) circuit, delay-line circuits, and the like. In some embodiments, mixed-signal analog circuits 603 may also include other test and/or power management circuits.

Input/output circuits 604 may be configured to coordinate data transfer between integrated circuit 600 and one or more peripheral devices. Such peripheral devices may include, without limitation, storage devices (e.g., magnetic or optical media-based storage devices including hard drives, tape drives, CD drives, DVD drives, etc.), audio processing subsystems, or any other suitable type of peripheral devices. In some embodiments, input/output circuits 604 may be configured to implement a version of Universal Serial Bus (“USB”) protocol or IEEE 1394 (Firewire®) protocol.

Input/output circuits 604 may also be configured to coordinate data transfer between integrated circuit 600 and one or more devices (e.g., other computing systems or integrated circuits) coupled to integrated circuit 600 via a network. In one embodiment, input/output circuits 604 may be configured to perform data processing necessary to implement an Ethernet (IEEE 802.3) networking standard such as Gigabit Ethernet or 10-Gigabit Ethernet, for example. It is possible and contemplated that, in other embodiments, input/output circuits 604 may implement any suitable networking standard. In some embodiments, input/output circuits 604 may be configured to implement multiple discrete network interface ports.

To summarize, various embodiments of a jitter sensor circuit are disclosed. Broadly speaking, a reference circuit may be configured to generate a reference voltage using a power supply voltage. A time-to-voltage converter circuit may be configured, in response to being activated, to generate a sample signal using the reference voltage. A voltage level of the sample signal can be proportional to a period of time a clock signal is a particular logic value. A control circuit may be configured to activate the time-to-voltage converter circuit at random time points, and an analog-to-digital converter circuit may be configured to generate, using the reference voltage, an output signal based on the sample signal. The output signal may include a plurality of bits whose value is indicative of the period of time the clock signal is the particular logic value

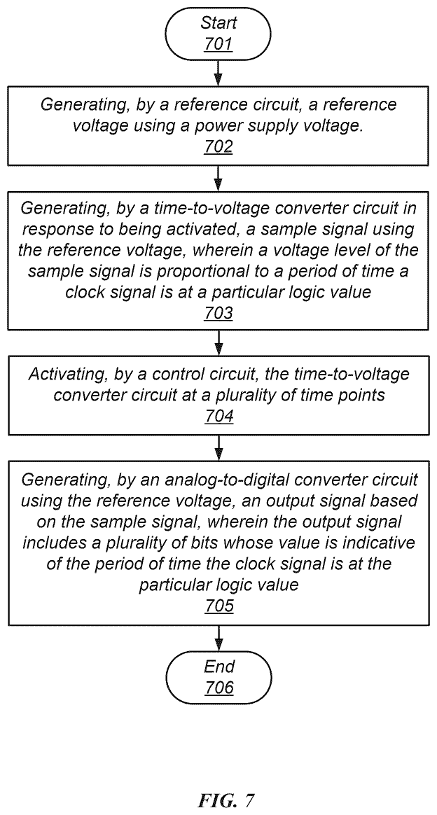

Turning to FIG. 7,.a flow diagram depicting an embodiment of a method for operating a jitter sensor circuit is illustrated. The method, which may be applied to various jitter sensor circuits, e.g., jitter sensor circuit 100 as depicted in FIG. 1, begins in block 701.

The method includes generating, by a reference circuit, a reference voltage using a power supply voltage (block 702). In various embodiments, generating the reference voltage may include generating a current from the power supply voltage to a ground supply node using a plurality of resistors, and generating the reference voltage using the current.

The method further includes generating, by a time-to-voltage converter circuit in response to being activated, a sample signal using the reference voltage (block 703). In various embodiments, a voltage level of the sample signal is proportional to a period of time a clock signal is at a particular logic value.

The method also includes activating, by a control circuit, the time-to-voltage converter circuit at a plurality of time points (block 704). In some embodiments, activating the time-to-voltage converter circuit at a plurality of time points includes waiting a random time period between a first activation of the time-to-voltage converter circuit and a second activation of the time-to-voltage converter circuit. In various embodiments, the time-to-voltage converter circuit includes an amplifier circuit, a capacitor coupled between an output of the amplifier circuit and an input of the amplifier circuit, and a resistor coupled between the input of the amplifier circuit and a switch. In such cases, generating the sample signal may include setting the voltage of the sample signal to the reference voltage during a reset period, and decreasing, during the period of time the clock signal is at the particular logic value, the voltage level of the sample signal by an amount proportional to a reciprocal of a product of a first value of the capacitor and a second value of the resistor.

The method further includes generating, by an analog-to-digital converter circuit using the reference voltage, an output signal based on the sample signal (block 705). In various embodiments, the output signal includes a plurality of bits whose value is indicative of the period of time the clock signal is at the particular logic value. In some embodiments, generating the output signal includes offsetting, by the analog-to-digital converter circuit, the sample signal. Offsetting the sample signal may, in other embodiments, include adding the reference voltage to the sample signal.

In various embodiments, generating the output signal includes converting, by the analog-to-digital converter circuit, the output signal to a feedback voltage using the reference voltage, and performing, by the analog-to-digital converter circuit, a comparison of the feedback voltage to the sample signal. In such cases, the method may additionally include adjusting the output signal using a result of the comparison. In some cases, the analog-to-digital converter circuit may include a plurality of capacitors whose respective first terminals are coupled to a summation node, and converting the output signal to the feedback voltage includes coupling respective second terminals of the plurality of capacitors to the reference voltage based on values of corresponding bits of the plurality of bits included in the output signal.

In some embodiments, the method also includes charging, by the analog-to-digital converter circuit, a capacitor using the reference voltage during a first time period, and decoupling, by the analog-to-digital converter circuit, the capacitors from the reference voltage during the second time period. In such cases, the method may further include generating, by the analog-to-digital converter circuit, the output signal using a second voltage level of the capacitor during the second time period. The method concludes in block 706.

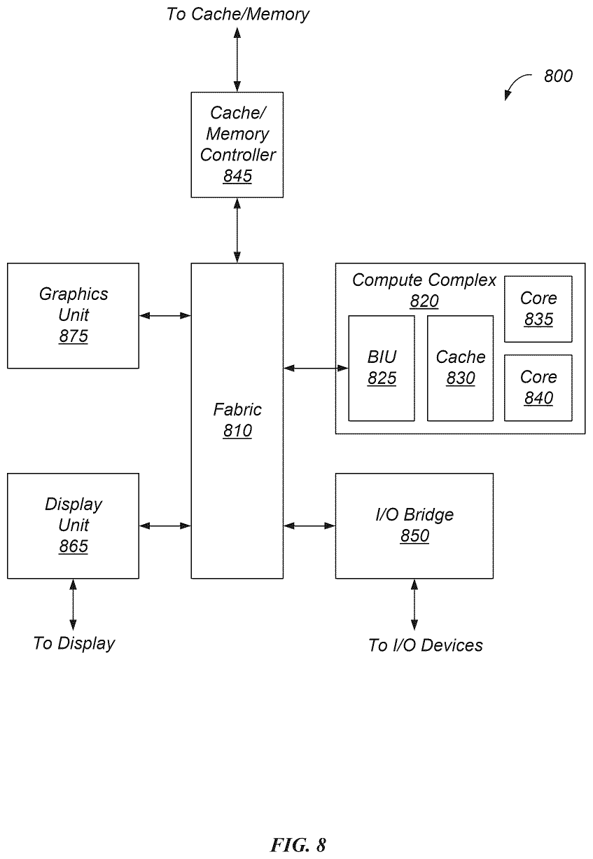

Referring now to FIG. 8, a block diagram illustrating an example embodiment of a device is shown. In various embodiments, device 800 may implement functionality of jitter sensor circuit 100 as depicted in FIG. 1. In some embodiments, elements of device 800 may be included within a system on a chip. In some embodiments, device 800 may be included in a mobile device, which may be battery-powered. Therefore, power consumption by device 800 may be an important design consideration. In the illustrated embodiment, device 800 includes fabric 810, compute complex 820, input/output (I/O) bridge 850, cache/memory controller 845, graphics unit 875, and display unit 865. In some embodiments, device 800 may include other components (not shown) in addition to, or in place of, the illustrated components, such as video processor encoders and decoders, image processing or recognition elements, computer vision elements, etc.

Fabric 810 may include various interconnects, buses, MUX's, controllers, etc., and may be configured to facilitate communication between various elements of device 800. In some embodiments, portions of fabric 810 may be configured to implement various different communication protocols. In other embodiments, fabric 810 may implement a single communication protocol, and elements coupled to fabric 810 may convert from the single communication protocol to other communication protocols internally.

In the illustrated embodiment, compute complex 820 includes bus interface unit (BIU) 825, cache 830, and cores 835 and 840. In various embodiments, compute complex 820 may include various numbers of processors, processor cores, and caches. For example, compute complex 820 may include 1, 2, or 4 processor cores, or any other suitable number. In one embodiment, cache 830 is a set associative L2 cache. In some embodiments, cores 835 and 840 may include internal instruction and data caches. In some embodiments, a coherency unit (not shown) in fabric 810, cache 830, or elsewhere in device 800, may be configured to maintain coherency between various caches of device 800. BIU 825 may be configured to manage communication between compute complex 820 and other elements of device 800. Processor cores, such as cores 835 and 840, may be configured to execute instructions of a particular instruction set architecture (ISA) which may include operating system instructions and user application instructions. These instructions may be stored in a computer readable medium such as a memory coupled to cache/memory controller 845 as discussed below.

As used herein, the term “coupled to” may indicate one or more connections between elements, and a coupling may include intervening elements. For example, in FIG. 8, graphics unit 875 may be described as “coupled to” a memory through fabric 810 and cache/memory controller 845. In contrast, in the illustrated embodiment of FIG. 8, graphics unit 875 is “directly coupled” to fabric 810 because there are no intervening elements.

Cache/memory controller 845 may be configured to manage transfer of data between fabric 810 and one or more caches and memories. For example, cache/memory controller 845 may be coupled to an L3 cache, which may, in turn, be coupled to a system memory. In other embodiments, cache/memory controller 845 may be directly coupled to a memory. In some embodiments, cache/memory controller 845 may include one or more internal caches. Memory coupled to cache/memory controller 845 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 845 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 820 to cause the computing device to perform functionality described herein.

Graphics unit 875 may include one or more processors, e.g., one or more graphics processing units (GPUs). Graphics unit 875 may receive graphics-oriented instructions, such as OPENGL®, Metal®, or DIRECT3D® instructions, for example. Graphics unit 875 may execute specialized GPU instructions or perform other operations based on the received graphics-oriented instructions. Graphics unit 875 may generally be configured to process large blocks of data in parallel, and may build images in a frame buffer for output to a display, which may be included in the device or may be a separate device. Graphics unit 875 may include transform, lighting, triangle, and rendering engines in one or more graphics processing pipelines. Graphics unit 875 may output pixel information for display images. Graphics unit 875, in various embodiments, may include programmable shader circuitry which may include highly parallel execution cores configured to execute graphics programs, which may include pixel tasks, vertex tasks, and compute tasks (which may or may not be graphics-related).

Display unit 865 may be configured to read data from a frame buffer and provide a stream of pixel values for display. Display unit 865 may be configured as a display pipeline in some embodiments. Additionally, display unit 865 may be configured to blend multiple frames to produce an output frame. Further, display unit 865 may include one or more interfaces (e.g., MIPI® or embedded display port (eDP)) for coupling to a user display (e.g., a touchscreen or an external display).

I/O bridge 850 may include various elements configured to implement universal serial bus (USB) communications, security, audio, and low-power always-on functionality, for example. I/O bridge 850 may also include interfaces such as pulse-width modulation (PWM), general-purpose input/output (GPIO), serial peripheral interface (SPI), and inter-integrated circuit (I2C), for example. Various types of peripherals and devices may be coupled to device 800 via I/O bridge 850.

In some embodiments, device 800 includes network interface circuitry (not explicitly shown), which may be connected to fabric 810 or I/O bridge 850. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 800 with connectivity to various types of other devices and networks.

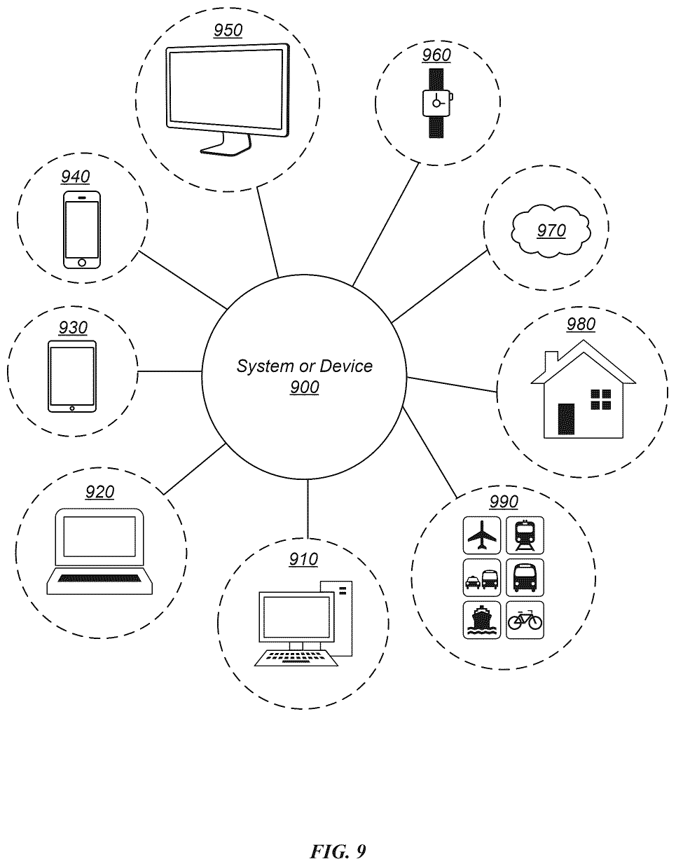

Turning now to FIG. 9, various types of systems that may include any of the circuits, devices, or systems discussed above are illustrated. System or device 900, which may incorporate or otherwise utilize one or more of the techniques described herein, may be utilized in a wide range of areas. For example, system or device 900 may be utilized as part of the hardware of systems such as a desktop computer 910, laptop computer 920, tablet computer 930, cellular or mobile phone 940, or television 950 (or set-top box coupled to a television).

Similarly, disclosed elements may be utilized in a wearable device 960, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 900 may also be used in various other contexts. For example, system or device 900 may be utilized in the context of a server computer system, such as a dedicated server or on shared hardware that implements a cloud-based service 970. Still further, system or device 900 may be implemented in a wide range of specialized everyday devices, including devices 980 commonly found in the home such as refrigerators, thermostats, security cameras, etc. The interconnection of such devices is often referred to as the “Internet of Things” (IoT). Elements may also be implemented in various modes of transportation. For example, system or device 900 could be employed in the control systems, guidance systems, entertainment systems, etc. of various types of vehicles 990.

The applications illustrated in FIG. 9 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

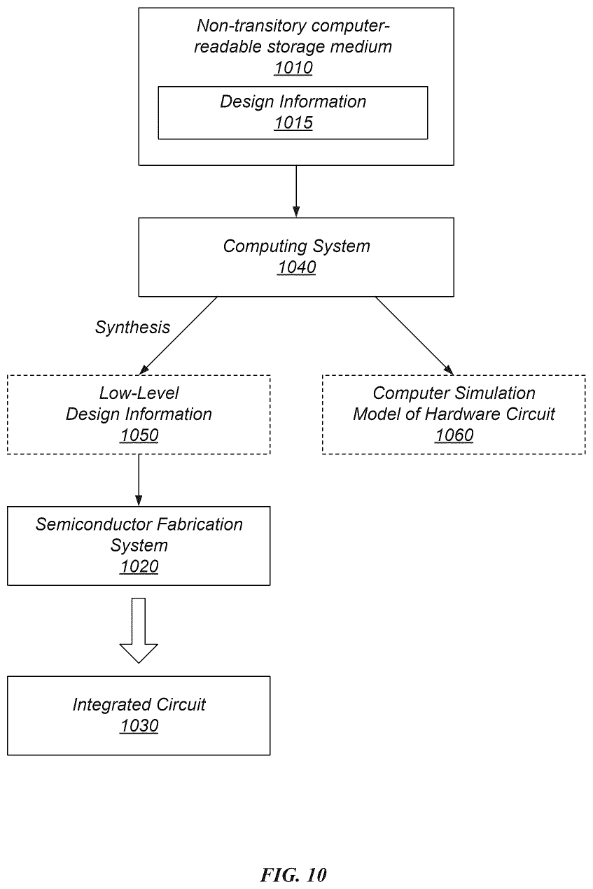

FIG. 10 is a block diagram illustrating an example of a non-transitory computer-readable storage medium that stores design information 1015, according to some embodiments. In the illustrated embodiment, computing system 1040 is configured to process design information 1015. This may include executing instructions included in design information 1015, interpreting instructions included in design information 1015, compiling, transforming, or otherwise updating design information 1015, etc. Therefore, design information 1015 controls computing system 1040 (e.g., by programming computing system 1040) to perform various operations discussed below, in some embodiments.

In the illustrated example, computing system 1040 processes design information 1015 to generate both computer simulation model of hardware circuit 1060 and low-level design information 1050. In other embodiments, computing system 1040 may generate only one of these outputs, may generate other outputs based on design information 1015, or both. Regarding computer simulation model of hardware circuit 1060, computing system 1040 may execute instructions of a hardware description language that includes register transfer level (RTL) code, behavioral code, structural code, or some combination thereof. The simulation model may perform the functionality specified by design information 1015, facilitate verification of the functional correctness of the hardware design, generate power consumption estimates, generate timing estimates, etc.

In the illustrated example, computing system 1040 also processes design information 1015 to generate low-level design information 1050 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1050 (potentially among other inputs), semiconductor fabrication system 1020 is configured to fabricate integrated circuit 1030 (which may correspond to functionality of the computer simulation model of hardware circuit 1060). Note that computing system 1040 may generate different simulation models based on design information at various levels of description, including low-level design information 1050, design information 1015, and so on. The data representing low-level design information 1050 and computer simulation model of hardware circuit 1060 may be stored on non-transitory computer-readable storage medium 1010, or on one or more other media.

In some embodiments, low-level design information 1050 controls (e.g., programs) semiconductor fabrication system 1020 to fabricate integrated circuit 1030. Thus, when processed by the fabrication system, the design information may program the fabrication system to fabricate a circuit that includes various circuitry disclosed herein.

Non-transitory computer-readable storage medium 1010 may comprise any of various appropriate types of memory devices or storage devices. Non-transitory computer-readable storage medium 1010 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 1010 may include other types of non-transitory memory as well, or combinations thereof. Accordingly, non-transitory computer-readable storage medium 1010 may include two or more memory media, which may reside in different locations for example, in different computer systems that are connected over a network.

Design information 1015 may be specified using any of various appropriate computer languages, including hardware description languages such as, without limitation: VHDL, Verilog, SystemC, System Verilog, RHDL, M, MyHDL, etc. The format of various design information may be recognized by one or more applications executed by computing system 1040, semiconductor fabrication system 1020, or both. In some embodiments, design information 1015 may also include one or more cell libraries that specify the synthesis, layout, or both of integrated circuit 1030. In some embodiments, design information 1015 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1030 may, in various embodiments, include one or more custom macrocells, such as memories, analog or mixed-signal circuits, and the like. In such cases, design information 1015 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1020 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1020 may also be configured to perform various testing of fabricated circuits for correct operation.

In various embodiments, integrated circuit 1030 and computer simulation model of hardware circuit 1060 are configured to operate according to a circuit design specified by design information 1015, which may include performing any of the functionality described herein. For example, integrated circuit 1030 may include any of various elements shown in FIGS. 1-6. Further, integrated circuit 1030 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1015. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1015 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1050. Low-level design information 1050 may program semiconductor fabrication system 1020 to fabricate integrated circuit 1030.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . W, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112 (f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a reference circuit configured to generate a reference voltage using a power supply voltage;
a time-to-voltage converter circuit configured, in response to being activated, to generate a sample signal using the reference voltage, wherein a first voltage level of the sample signal is proportional to a portion of a period of a clock signal;
a control circuit configured to activate the time-to-voltage converter circuit at a plurality of time points; and
an analog-to-digital converter circuit configured to generate, using the reference voltage, an output signal based on the sample signal, wherein the output signal includes a plurality of bits whose value is indicative of the period of time the clock signal is the particular logic value.

2. The apparatus of claim 1, wherein to generate the output signal, the analog-to-digital converter circuit is further configured to:
charge a capacitor using the reference voltage during a first time period;
decouple the capacitor from the reference voltage during a second time period; and
generate the output signal using a second voltage level of the capacitor during the second time period.

3. The apparatus of claim 1, wherein to generate the output signal, the analog-to-digital converter circuit is further configured to offset the sample signal using the reference voltage.

4. The apparatus of claim 1, wherein to generate the output signal, the analog-to-digital converter circuit is configured to:
convert the output signal to a feedback voltage using the reference voltage;
perform a comparison of the feedback voltage to the sample signal; and
adjust the output signal using a result of the comparison.

5. The apparatus of claim 1, wherein the time-to-voltage converter circuit includes an amplifier circuit, a capacitor coupled between an output of the amplifier circuit and an input of the amplifier circuit, and a resistor coupled between the input of the amplifier circuit and a switch, and wherein to generate the sample signal, the time-to-voltage converter circuit is further configured to:
set the sample signal to the reference voltage during a reset period; and
change, during an integration period, the sample signal by an amount proportional to a reciprocal of a product of a first value of the capacitor and a second value of the resistor.

6. The apparatus of claim 1, wherein to activate the time-to-voltage converter circuit at a plurality of time points, the control circuit is further configured to wait a random time period between a first activation of the time-to-voltage converter circuit and a second activation of the time-to-voltage converter circuit.

7. A method, comprising:
generating, by a reference circuit, a reference voltage using a power supply voltage;
generating, by a time-to-voltage converter circuit in response to being activated, a sample signal using the reference voltage, wherein a first voltage level of the sample signal is proportional to a period of time a clock signal is at a particular logic value;
activating, by a control circuit, the time-to-voltage converter circuit at a plurality of time points; and
generating, by an analog-to-digital converter circuit using the reference voltage, an output signal based on the sample signal, wherein the output signal includes a plurality of bits whose value is indicative of the period of time the clock signal is the particular logic value.

8. The method of claim 7, wherein generating the output signal includes:
charging, by the analog-to-digital converter circuit, a capacitor using the reference voltage during a first time period;
decoupling, by the analog-to-digital converter circuit, the capacitor from the reference voltage during a second time period; and
generating, by the analog-to-digital converter circuit, the output signal using a second voltage level of the capacitor during the second time period.

9. The method of claim 7, further comprising offsetting, by the analog-to-digital converter circuit, the sample signal using the reference voltage.

10. The method of claim 7, wherein generating the output signal includes:
converting the output signal to a feedback voltage using the reference voltage;
performing a comparison of the feedback voltage to the sample signal; and
adjusting the output signal using a result of the comparison.

11. The method of claim 10, wherein the analog-to-digital converter circuit includes a plurality of capacitors whose respective first terminals are coupled to an input node, and wherein converting the output signal to the feedback voltage includes coupling respective second terminals of the plurality of capacitors to the reference voltage based on values of corresponding bits of the plurality of bits.

12. The method of claim 7, wherein the time-to-voltage converter circuit includes an amplifier circuit, a capacitor coupled between an output of the amplifier circuit and an input of the amplifier circuit, and a resistor coupled between the input of the amplifier circuit and a switch, and wherein generating the sample signal includes:
setting the first voltage level of the sample signal to the reference voltage during a reset period; and
decreasing, during the period of time the clock signal is at the particular logic value, the first voltage level of the sample signal by an amount proportional to a reciprocal of a product of a first value of the capacitor and a second value of the resistor.

13. The method of claim 7, wherein activating the time-to-voltage converter circuit at a plurality of time points includes waiting a random time period between a first activation of the time-to-voltage converter circuit and a second activation of the time-to-voltage converter circuit.

14. An apparatus, comprising:
a clock generation circuit configured to generate a clock signal;
a plurality of circuit blocks configured to receive the clock signal; and
a jitter sensor circuit configured to:
generate a reference voltage using a power supply voltage;
generate, at random time points, a sample signal using the reference voltage, wherein a first voltage level of the sample signal is proportional to a period of time the clock signal is at a particular logic value; and
generate an output signal based on the sample signal, wherein the output signal includes a plurality of bits whose value is indicative of the period of time the clock signal is the particular logic value.

15. The apparatus of claim 14, wherein the jitter sensor circuit includes an analog-to-digital converter circuit that includes a capacitor, and wherein to generate the output signal, the jitter sensor circuit is further configured to:
charge the capacitor using the reference voltage during a first time period;
decouple the capacitor from the reference voltage during a second time period; and
generate the output signal using a second voltage level of the capacitor during the second time period.

16. The apparatus of claim 14, wherein the jitter sensor circuit is further configured to offset the sample signal using the reference voltage.

17. The apparatus of claim 14, wherein to generate the output signal, the jitter sensor circuit is further configured to:
convert the output signal to a feedback voltage using the reference voltage;
perform a comparison of the feedback voltage to the sample signal; and
adjust the output signal using a result of the comparison.

18. The apparatus of claim 17, wherein the jitter sensor circuit includes an analog-to-digital converter circuit and a plurality of capacitors whose respective first terminals are coupled to an input node of the analog-to-digital converter circuit, and wherein to convert the output signal to the feedback voltage, the jitter sensor circuit is further configured to couple respective second terminals of the plurality of capacitors to the reference voltage based on values of corresponding bits of the plurality of bits.

19. The apparatus of claim 14, wherein the jitter sensor circuit includes a time-to-voltage converter circuit that includes an amplifier circuit, a capacitor coupled between an output of the amplifier circuit and an input of the amplifier circuit, and a resistor coupled between the input of the amplifier circuit and a switch, and wherein to generate the sample signal, the jitter sensor circuit is further configured to:
set the first voltage level of the sample signal to the reference voltage during a reset period; and
decrease, during the period of time the clock signal is at the particular logic value, the first voltage level of the sample signal by an amount proportional to a reciprocal of a product of a first value of the capacitor and a second value of the resistor.

20. The apparatus of claim 14, wherein the jitter sensor circuit includes a plurality of resistors, and wherein to generate the reference voltage, the jitter sensor circuit is further configured to:
generate a current from the power supply voltage to a ground supply node using the plurality of resistors; and
generate the reference voltage using the current.
